(19) United States
(12) Patent Application Publication
(10) Pub. No.: US 2025/0067774 A1
(43) Pub. Date: Feb. 27, 2025

(54) PROBE

(71) Applicant: ROLLS-ROYCE plc., London (GB)

(72) Inventors: Xin DONG, Nottingham (GB); Jing LIU, Nottingham (GB); Dragos A. AXINTE, Nottingham (GB); Andrew D. NORTON, Derby (GB)

(73) Assignee: ROLLS-ROYCE plc., London (GB)

(21) Appl. No.: 18/791,814

(22) Filed: Aug. 1, 2024

(30) Foreign Application Priority Data
Aug. 25, 2023 (GB) 2312987.7

(51) Int. Cl. G01R 1/067; G01M 15/02; G01M 15/04

(52) U.S. Cl. CPC G01R 1/067; G01M 15/02; G01M 15/04

(57) ABSTRACT

An inflatable probe for testing a component. The inflatable probe has a balloon formed of a dielectric material, the balloon having a neck and at least one electrode pair comprising an inner electrode and an outer electrode, the inner electrode being positioned on an internal surface of the balloon and the outer electrode being positioned on an external surface of the balloon. The inflatable probe also has a sealing plug that forms an air tight seal with neck of the balloon to retain a fluid within the balloon, the sealing plug at least having a seal electrode to connect to the inner electrode within the balloon, the sealing plug supporting a first wire to connect to a first seal electrode. The inflatable probe also has at least one tool that is connected to the balloon.

### CROSS-REFERENCE TO RELATED APPLICATIONS

This specification is based upon and claims the benefit of priority from United Kingdom patent application number GB 2312987.7 filed on Aug. 25, 2023, the entire contents of which is incorporated herein by reference.

### BACKGROUND

### Technical Field

The present disclosure relates to an inflatable probe for testing a component. In particular, the disclosure relates to an inflatable probe in the form of a dielectric elastomer balloon that is able to be deformed to position itself within a complex system with confined spaces, e.g. within electrical equipment such as an electrical motor.

### Description of the Related Art

Complex systems are used in a number of areas of technology. They are complex in that they include both moving and static parts. In power generation, complex systems include turbines and engines. Electrical equipment is being more commonly used in power generation systems. Part of the reason for this is that engineers are looking for ways of reducing emissions of carbon dioxide; this is especially true in propulsion systems where fossil fuel-based combustion engines are being replaced with electrical motors connected to battery packs.

Electrical power for vehicular systems is seen to be a greater part of future designs as the technology develops. However, one of the issues with using electrical power, rather than the combustion of fossil fuels, is that electrical power requires new methods to test, probe and repair electrical motors. This is because gaps between components in electrical motors tend to be much smaller than they are in combustion engines. Furthermore, many other systems, such as nuclear power, oil and gas production and telecoms systems have complex systems that are located within confined spaces. Consequently, the requirements for in situ repairs are much more complex as the classical tools that have been used for testing and repairing older systems are often not suitable for these complex systems.

In the electrical field for example, one area in which there can be problems is in the detecting, monitoring and repairing of faults on or near a rotor or a stator. Conventional borescope and robotic inspection devices are often too large to fit in the gaps between components.

There is therefore a need for new robotics systems that can deliver a robotic probe to a required area within a complex system, e.g. an electrical motor, to perform a test or repair and if required to move a probe or tool within a confined space to effect that test or repair, without damaging other components of the system, e.g. rotors, stators, windings or contacts or wires within the system. In other words, new designs for robotics need to be developed to overcome the limitations of conventional tools for testing and repairing machinery.

### SUMMARY

In a first aspect there is provided an inflatable probe for testing a component, the probe comprising: a balloon formed of a dielectric material, the balloon having a neck and at least one electrode pair comprising an inner electrode and an outer electrode, the inner electrode being positioned on an internal surface of the balloon and the outer electrode being positioned on an external surface of the balloon; a sealing plug that forms an air tight seal with the neck of the balloon to retain a fluid within the balloon, the sealing plug at least having a seal electrode to connect to the inner electrode within the balloon, the sealing plug supporting a first wire to connect to a first seal electrode; and at least one tool that is connected to the balloon.

In some embodiments a second seal electrode are provided around the external surface of the balloon and the sealing plug, so as to seal the balloon against the sealing plug, and the second seal electrode is provided with an electrical contact to connect to the outer electrode.

In some embodiments each inner electrode and each outer electrode are flexible electrodes.

In some embodiments each internal electrode is formed of at least one of graphene, carbon nanotubes, and metallic nanotubes.

In some embodiments there may be from 2 to 12 pairs of inner electrodes and outer electrodes.

In some embodiments there are a plurality of parallel arranged inflatable balloons each with separate pairs of inner electrodes and outer electrodes to enable positioning of the sensor relative to the component of interest.

In some embodiments the at least one tool is one or more of a charge-coupled device, a complementary metal-oxide semiconductor chip, a Hall effect sensor, and a grabbing implement.

In some embodiments the first wire that is connected to the first seal electrode and a second wire that is connected to the second seal electrode are coupled to control voltage sources to provide a controlled supply of voltage to the at least one electrode pair.

In some embodiments a voltage supply is connected to a computer to control the supply of voltage to the at least one electrode pair, the computer also being used to receive signals from the inflatable probe.

In some embodiments a conduit is provided in the sealing plug for supplying fluid and removing fluid from the balloon.

In a second aspect there is provided a method of testing a component using the inflatable probe of the first aspect, the method comprising the steps of: inserting the inflatable probe of the first aspect into a workspace; moving the inflatable probe within the workspace to a component of interest for testing; testing the component using the at least one tool of the inflatable probe; and removing the inflatable probe away from the component and out of the workspace.

In some embodiments the inflatable probe is moved by applying controlled voltages to the electrodes of the balloon.

In some embodiments the inflatable probe is moved to different locations with respect to the component for further testing or to a different component of interest for testing before the inflatable probe is removed from the workspace.

In some embodiments the workspace is an engine.

The skilled person will appreciate that except where mutually exclusive, a feature described in relation to any one of the above aspects may be applied mutatis mutandis to any other aspect. Furthermore, except where mutually exclusive any feature described herein may be applied to any aspect and/or combined with any other feature described herein.

### BRIEF DESCRIPTION OF THE DRAWINGS

Embodiments will now be described by way of example only, with reference to the Figures, in which:

FIG. 1a is a schematic perspective view of a first embodiment of an inflatable probe of the present disclosure;

FIG. 1b is a schematic cut-away perspective view of the inflatable probe of FIG. 1a;

FIG. 1c is a schematic close-up sectional view of a portion of the probe of FIGS. 1a and 1b to show the electrode structure;

FIG. 2a is a schematic close-up perspective view of the electrode structure of the inflatable probe shown in FIGS. 1a, 1b and 1c;

FIG. 2b is close-up schematic side view of the electrode structure of the inflatable probe shown in FIGS. 1a, 1b and 1c;

FIG. 3 is a schematic perspective view of a second embodiment of an inflatable probe of the present disclosure that has a plurality of electrode pairs distributed about the balloon structure of the probe;

FIG. 4 is a flow chart of a method of testing a component using an inflatable probe of the present disclosure.

### DETAILED DESCRIPTION

Aspects and embodiments of the present disclosure will now be discussed with reference to the accompanying figures. Further aspects and embodiments will be apparent to those skilled in the art.

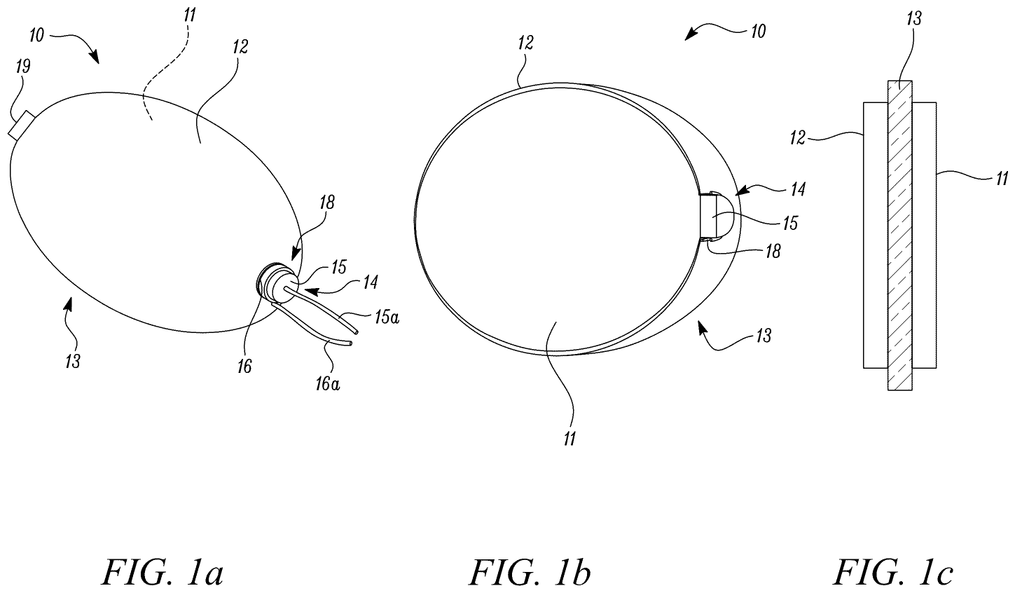

FIG. 1a is a schematic perspective view of a first embodiment of an inflatable probe of the present disclosure in the form of a dielectric elastomer balloon. In this a balloon 13 is provided (e.g. coated) with a compliant inner electrode (11) and an outer electrode 12. The inner electrode is positioned on the inside surface of the balloon 13, whilst the outer electrode 12 is positioned on the outside of the balloon 13. In FIG. 1a the balloon 13 is in an inflated state and contains a fluid e.g. a liquid or air. The fluid is sealed in the balloon using a sealing plug 14 that is position in a neck 18 of the probe. The sealing plug 14 provides a first seal electrode 15, which is used to engage with the inner electrode within the balloon 13, and has a wire 15a that is connected to the first seal electrode and passes through the sealing plug 14. The sealing plug 14 also has a second seal electrode 16 that is positioned around the outside of the sealing plug 14. In FIG. 1 the second seal electrode 16 in the form of a clip that forms around the balloon 13. The clip, which may be made of any suitable material, acts both as the second seal electrode for connecting with the outer electrode 12 on the surface of the balloon 13 and a clamp to hold the balloon 13 onto the sealing plug 14. FIG. 1a shows a wire 16a leading from the clip 16. The wire 16a is used to provide a voltage to the second seal electrode 16 and thus to the outer electrode 12 on the balloon. The balloon 13 itself is formed of a dielectric material, which may for example a rubber or latex or other deformable dielectric material. The inflatable probe has a tool 19 located on the balloon opposite the neck 18. There may be any suitable number of tools 19 positioned about the balloon 23. The tool 19 may be any suitable inspection tool or sensing device. For example the tool 19 may be a charge-coupled device (CCD) or complementary metal-oxide semiconductor (CMOS) chip for component inspection including non-destructive evaluation, or a Hall effect sensor for assessing magnetic field quality, or a grabbing implement for removal of foreign object damage. In FIG. 1a the tool 19 is a charge-coupled device (CCD) housed in a sensor head for digitally imaging components for non-destructive evaluation

FIG. 1b is a schematic cut-away image of the inflatable probe shown in FIG. 1a. FIG. 1b shows the inner electrode 11 of the inflatable probe 10 that is provided (e.g. coated) on the inside surface of the balloon 13 with the outer electrode 12 being provided on the outside surface of the balloon 13. The sealing plug 14 is also shown in the neck 18 of the balloon 13. The sealing plug 14 forms an airtight seal with the deformable dielectric material of the balloon 13. The first seal electrode is used to supply the voltage to the inner electrode 11 on the inner surface of the balloon 13 whilst the second seal electrode 16 provides the voltage to the outer electrode 12 on the outer surface of the balloon.

FIG. 1c is a schematic close-up view of the electrode structure of the probe of FIGS. 1a and 1b. The balloon 13 is formed of a deformable dielectric material, e.g. a latex. Coating the outer/external surface of the balloon 13 is the outer electrode 12. Coating the inner/internal surface of the balloon 13 is the inner electrode 11. As the balloon 13 is formed of a deformable dielectric material, it will stretch or decrease in size depending upon whether the balloon is inflated or deflated and the electrodes must also be able to stretch and deform with the dielectric material that they are formed around. If the inner electrode 11 and the outer electrode 12 are not able to deform they may well damage or break the balloon 13.

The electrodes may be made from any suitable deformable conducting material. In particular, this may a flexible host or matrix doped with materials such as graphene, carbon nanotubes, metallic nanotubes. Such coatings may be applied as a spray with a spray gun and then heated to cure. If the electrode and dielectric material are both made of a rubber, the adhesion between them and the rubber/latex balloon will be strong. Alternatively, it may be made from another suitable conductive polymer coated onto the inner or the outer surface of the balloon 13. Alternatively, it may be made of any other deformable electrode. The use of electrodes about a layer of flexible dielectric material means that this area of the balloon acts as an actuator. As such, the application of a voltage to the electrodes creates a pressure within the layer of flexible dielectric material and results in deformation of the shape of that layer. This deformation causes an extension/inflation or compression/deflation of the balloon. By attuning the electrode structure around the dielectric elastomer balloon allows for controlled deformation such that the actuator can be manipulated in shape.

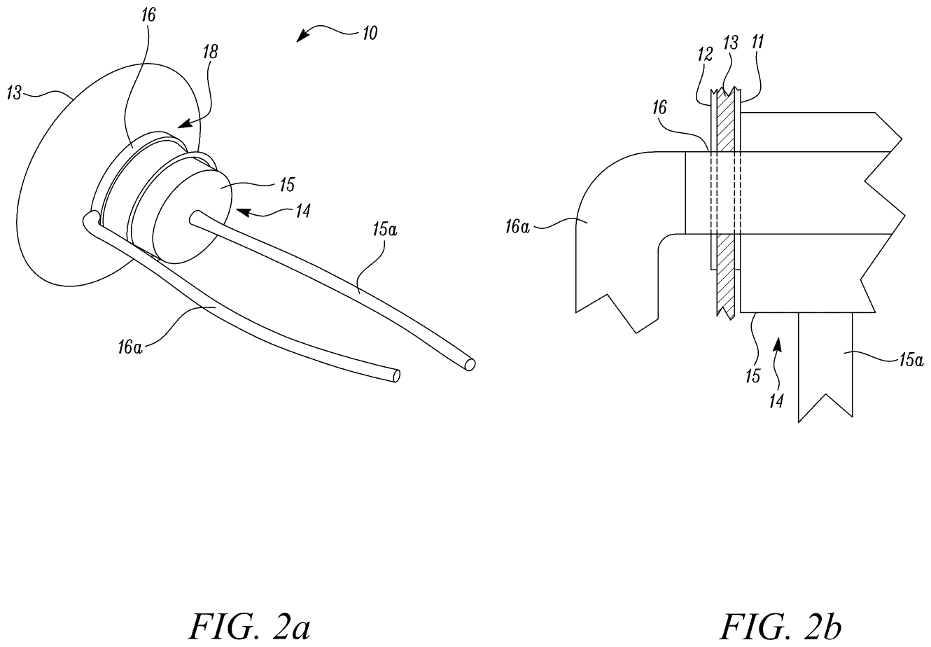

FIG. 2a is a schematic close-up perspective view of the electrode structure of the inflatable probe 10 shown in FIGS. 1a, 1b and 1c, more particularly the portion on and around the sealing plug 14 of the probe. The sealing plug 14 is used to maintain the volume of fluid within the balloon 13. The fluid may be a gas such as air, nitrogen, or a gas lighter than air such as helium. The sealing plug 14, which includes the first seal electrode 15, may be made from a solid material, e.g. a metal. The second seal electrode 16 may be provided on the sealing plug 14. Alternatively, as presented in FIG. 2a the second seal electrode 16 may be formed on a clip that also has a purpose to keep the balloon 13 attached to the sealing plug 14. The clip may be formed of any suitable material, e.g. a metal, a plastics material or a composite material. The second seal electrode 16 for contacting the outer electrode 12 on the balloon 13 is typically made from a solid material, e.g. a metal such as copper, which may be a copper strip. The advantage of using solid materials for the electrodes is that it allows for wire cables to be used, these can be easily connected to the electrodes. It also allows for easier connection with the balloon 13 that has a low surface energy.

FIG. 2b presents a close-up of the electrical connections within the inflatable probe 10. In FIG. 2b the balloon 13 is shown with the inner electrode 21 mounted on the inner surface of the balloon 13 and the outer electrode 22 mounted on the outer surface of the balloon 13. The sealing plug 14 with the first seal electrode 15 is shown abutting the inner electrode 11 of the balloon 13. The clip containing the second seal electrode 16 is shown contacting the outer electrode 12. In FIG. 2b the first wire 15a and the second wire 17 are shown to connect with the first seal electrode 15 and the second seal electrode 22 respectively. In this embodiment the first wire 15a is the negative wire and the second wire 16a is the positive wire. In this case the use of the clip for the second seal electrode 16 is beneficial as it imparts a force onto the balloon 13 and maintains the contact between the first and second seal electrodes and the inner and outer electrodes that are on the balloon 13. The sealing plug 14 may also have a conduit attached that allows for the inflation and deflation of the balloon at appropriate times.

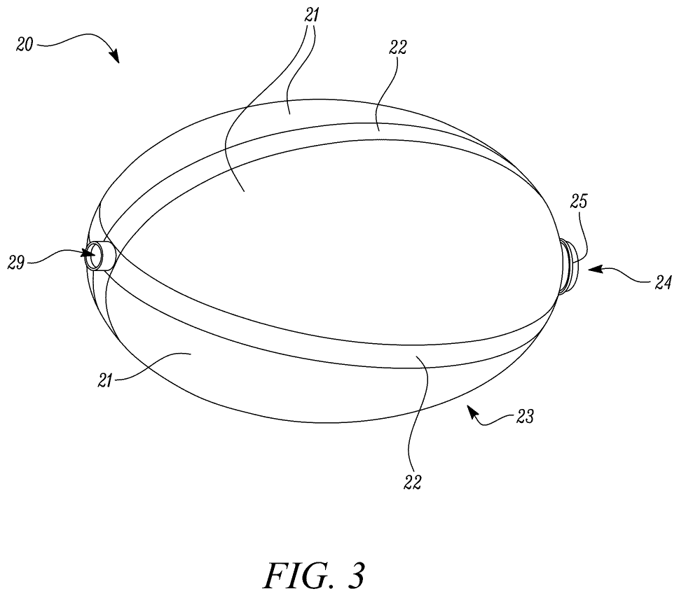

FIG. 3 is a schematic perspective view of a second embodiment of an inflatable probe 20 of the present disclosure. In this embodiment the balloon 23 is shown having a plurality of outer electrodes 21 positioned around the outer/external surface of the balloon 23. Each outer electrode 21 is separated from the neighbouring outer electrode 21 by a non-conducting area 22, which area is not covered with the electrode material. The position of the inner electrodes (not shown) on the inner/internal surface of the balloon 23 corresponds with the position of the outer electrodes, i.e. they are located on the opposing surface of the balloon 23. The sealing plug 24 has a number of first seal electrodes that connect with the positions of the inner electrodes. Each of these electrodes may have their voltage supplied by its own wire. Alternatively, the electrodes may have the voltage supplied through a single wire or they may be paired up to reduce the number of wires. The number of second seal electrodes on the sealing system, whether on the plug, clip or other sealing mechanism will be the same as the number of outer electrodes 21. Each of these are solid electrodes which pair with the outer electrodes. Similar to the first seal electrodes the second seal electrodes may be supplied by any suitable number of wires from a single wire, electrodes matched in groups to each electrode having its own wire. At the head of the probe is shown a tool 29. In FIG. 3 the tool 29 is a complementary metal-oxide semiconductor (CMOS) chip housed in a sensor head for digitally imaging components for non-destructive evaluation. There may be any suitable number of tools 29 positioned about the balloon 23. The tool 29 may be any suitable inspection tool or sensing device. For example the tool 19 may be a charge-coupled device (CCD) or complementary metal-oxide semiconductor (CMOS) chip for component inspection including non-destructive evaluation, or a Hall effect sensor for assessing magnetic field quality, or a grabbing implement for removal of foreign object damage. The response from the tool at the tip of the inflatable probe may be transmitted via electrical wires, optical fibres, or wireless methods such as Bluetooth® or Wi-Fi™ to the outside of the complex component under investigation.

By controlling the voltage to the electrodes, which are separated by the dielectric medium of the balloon, causes a deformation of the balloon about the electrode. The deformation of the balloon is a result of the forces acting upon it. When voltage is applied to the electrodes, an electric field is established within the thin dielectric layer of the balloon. The electric field causes Compressive Maxwell stress within the dielectric material of the balloon. This causes a reduction in the thickness of the dielectric material but an increase in the area of the dielectric material. Therefore, through the application of voltage it is possible to control the deformation of the balloon probe and thus allow it to move. By using a number of electrodes around the probe, the probe is able to move with a number of degrees of freedom. The balloon probe works by controlling the voltage to the electrodes so that the probe is able to move within a confined space to a point to sense or probe the system. In the case of a single electrode pair the balloon probe can crawl through the space, with more than one electrode pair the balloon can walk by expanding one electrode area whilst maintaining the other at the same length and repeating for the other electrode pair. The greater the number of electrode pairs and the more control that the system can have. However, the increase in the number of electrode pairs also increases the complexity of the system.

The probe can be inserted into the component to be inspected in an inflated or non-inflated state depending upon the size of the aperture. Once into a space the pressure within the balloon may be controlled by the addition or removal of a fluid. This allows the probe to either be able to slide through a gap with minimal contact with the walls or to crawl into a space if the balloon cannot be slid into the appropriate position. If the balloon is slid into position the balloon may be inflated so that contact with the component is maintained and inspection using the probe can take place. Although, this is described as slid, it may also apply to be floated into position if the fluid used is lighter than air. Changing the fluid as the balloon probe moves within the complex environment can assist the balloon to move through more complex environments.

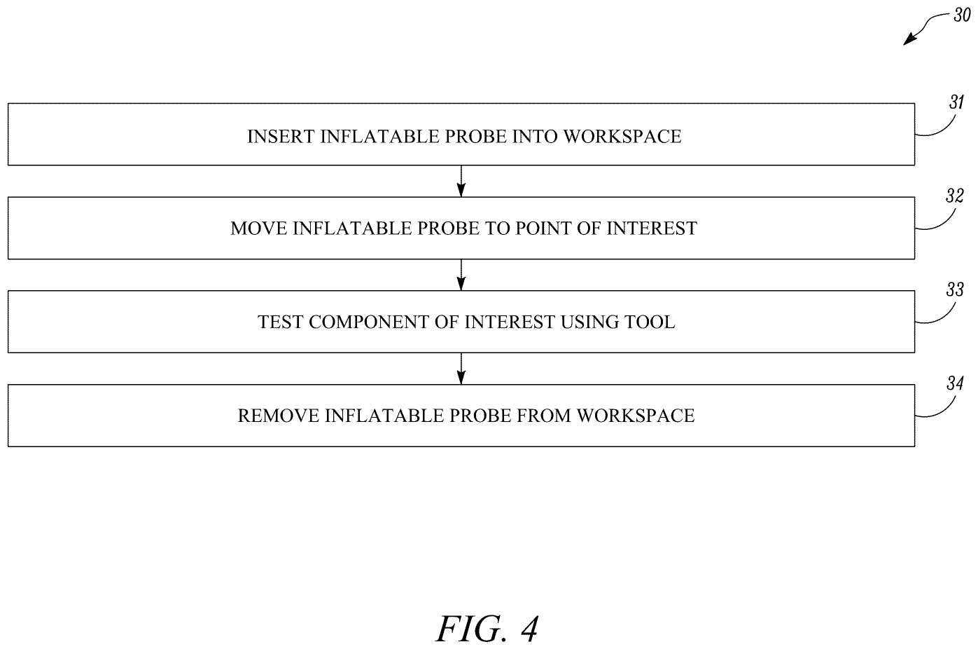

FIG. 4 presents a flow chart at the operation of the probe of the present disclosure in a method 30 of testing a component. In Step 31 the device is inserted into the working space. Access to the workspace may be through an access port, like a borescope port or similar, or the casing of the complex component may be removed or if there is small external access then the probe may be inserted through that access. With the probe inside the complex component the probe can be moved and positioned to a point that is of interest in Step 32. The number of electrode pairs on the balloon will determine in which planes it is possible to move the probe. In the case of a single electrode pair the probe will only be able to move in a single plane. If there are more electrode pairs then the number of planes that the balloon can move in increases so that it can access more difficult to reach regions of the component. The pressure in the balloon may be changed during the positioning step. This allows the balloon to move more easily and to reach narrower and more difficult to reach parts that are not accessible by other means. In Step 33 the testing using the sensor takes place. The testing may be to inspect for degradation of components or inclusion of foreign object debris in the electrical machine, or to non-visually assess the health of the asset such as through a Hall effect sensor to study the magnetic field quality. Depending upon the nature of the tests the balloon may be inflated to fill the cavity/volume that is being inspected. Inflation of the balloon may help to position the sensor against the size of the component within the cavity/volume. Once the testing has been performed the balloon may be moved to a second location. This may be done by moving the device using any cables. Alternatively, controlled voltage may be applied to the inner and outer electrodes on the balloon. By applying the controlled voltage allows the balloon to move itself within the space by crawling its way along at least one of the surfaces of the cavity/volume. Once the balloon is moved into the second or further desired location the sensor may perform more tests to build up a map or an image of the desired properties of the scan area of the component. Once the desired number of tests have been performed within the desired area of the component the balloon probe can be removed from the component-Step 34. Depending upon the nature of the area that has been probed the balloon may be inflated or deflated as appropriate and the electrodes activated if required so that the probe is able to crawl out of the area and then removed through the insertion hole.

The system may also comprise more than one balloons covered with their electrodes arranged within the system. The balloons may be arranged in parallel. The plurality of balloons may be as described above. Each balloon may have its own sealing plug or may have a single plug. The electrode pairs on the balloons may be able coupled or may each be individually addressable. The presence of a plurality of linked balloons, allows for the structure to move in a controlled way.

It will be understood that the invention is not limited to the embodiments above-described and various modifications and improvements can be made without departing from the concepts described herein. Except where mutually exclusive, any of the features may be employed separately or in combination with any other features and the disclosure extends to and includes all combinations and sub-combinations of one or more features described herein.

We claim:

1. An inflatable probe for testing a component, the inflatable probe comprising:
a balloon formed of a dielectric material, the balloon having a neck and at least one electrode pair comprising an inner electrode and an outer electrode, the inner electrode being positioned on an internal surface of the balloon and the outer electrode being positioned on an external surface of the balloon;
a sealing plug that forms an air tight seal with neck of the balloon to retain a fluid within the balloon, the sealing plug at least having a seal electrode to connect to the inner electrode within the balloon, the sealing plug supporting a first wire to connect to a first seal electrode; and
at least one tool that is connected to the balloon.

2. The inflatable probe of claim 1, wherein a second seal electrode is provided around the external surface of the balloon and the sealing plug, so as to seal the balloon against the sealing plug, and the second seal electrode is provided with an electrical contact to connect to the outer electrode.

3. The inflatable probe of claim 1, wherein each inner electrode and each outer electrode are flexible electrodes.

4. The inflatable probe of claim 3, wherein each inner electrode is formed of at least one of graphene, carbon nanotubes, and metallic nanotubes.

5. The inflatable probe of claim 1, wherein there are from 2 to 12 pairs of inner electrodes and outer electrodes.

6. The inflatable probe of claim 5, wherein there are a plurality of parallel arranged inflatable balloons each with separate pairs of inner electrodes and outer electrodes to enable positioning of the tool with respect to the component.

7. The inflatable probe of claim 1, wherein the at least one tool is one or more of a charge-coupled device, a complementary metal-oxide semiconductor chip, a Hall effect sensor, and a grabbing implement.

8. The inflatable probe of claim 2, wherein the first wire that is connected to the first seal electrode and a second wire that is connected to the second seal electrode are coupled to control voltage sources to provide a controlled supply of voltage to the at least one electrode pair.

9. The inflatable probe of claim 8, wherein a voltage supply is connected to a computer to control the supply of voltage to the at least one electrode pair, the computer also being used to receive signals from the inflatable probe.

10. The inflatable probe of claim 1, wherein a conduit is provided in the sealing plug for supplying fluid and removing fluid from the balloon.

11. A method of testing a component using the inflatable probe of claim 1, the method comprising the steps of:
inserting the inflatable probe of claim 1 into a workspace;
moving the inflatable probe within the workspace to a component of interest for testing;
testing the component using the at least one tool of the inflatable probe; and
removing the inflatable probe away from the component and out of the workspace.

12. The method of claim 11, wherein the inflatable probe is moved by applying controlled voltages to the electrodes of the balloon.

13. The method of claim 11, wherein the inflatable probe is moved to different locations with respect to the component for further testing or to a different component of interest for testing before the inflatable probe is removed from the workspace.

14. The method of claim 11, where the workspace is an engine.
